(19) United States
(12) Patent Application Publication
(10) Pub. No.: US 2004/0165452 A1
(43) Pub. Date: Aug. 26, 2004

(54) Semiconductor memory device including RAS guarantee circuit

(75) Inventor: Masaya Nakano, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/689,062

(22) Filed: Oct. 21, 2003

(30) Foreign Application Priority Data
Feb. 25, 2003 (JP) 2003-047174(P)

(51) Int. Cl. G11C 7/00

(52) U.S. Cl. 365/193

(57) ABSTRACT

An internal RAS generating circuit generates an internal signal instructing activation of a word line, based on a control command received from the outside. The internal RAS generating circuit activates the internal signal at least during a period in which an internal RAS guarantee signal received from an internal RAS guarantee signal generating circuit is asserted, regardless of the control command instructing inactivation of the word line. In a normal operation mode, the internal RAS guarantee signal generating circuit activates the internal RAS guarantee signal until a prescribed period guaranteeing a restoring operation elapses, while in the test mode, it inactivates the internal RAS guarantee signal.

### BACKGROUND OF THE INVENTION

1. Field of the Invention

The present invention relates to a semiconductor memory device, and more particularly to a semiconductor memory device including an RAS (Row Address Strobe) guarantee circuit guaranteeing a prescribed, internal row activation time period.

2. Description of the Background Art

As an operation test in a DRAM (Dynamic Random Access Memory), which is one of representative semiconductor memory devices, an operation margin test of a memory cell by reducing an active period of a word line is known. (Hereinafter, the active period is also referred to as an “RAS width”, and in particular, the active period set from the outside of the DRAM is referred to as an “external RAS width”, and the actual active period within the DRAM is referred to as an “internal RAS width.”)

In other words, in the DRAM, when a memory cell is accessed, data in other memory cells commonly connected to a word line to which the selected memory cell is connected is also destroyed. Therefore, an operation for restoring the data to the memory cell is performed with a sensing operation by a sense amplifier. Here, if there is a memory cell in which an access transistor connecting a data line (a bit line) to a capacitor storing data has low current drivability, the restoring operation cannot be completed within the active period of the word line in that memory cell.

In such a defective memory cell with low current drivability, recharging to the memory cell in the restoring operation is not performed in a satisfactory manner, and therefore, subsequent sensing operation will be poor. Here, by testing the operation margin of the memory cell with the internal RAS width actively reduced, the defective memory cell with low current drivability can be detected and eliminated.

As another operation test in the DRAM, Japanese Patent Laying-Open No. 2000-21197 discloses a test method by reducing write command read time tRWL or precharge time tPR. In order to address the problem that the test with reduced write command read time tRWL and precharge time tPR cannot sufficiently be conducted due to constraints of measuring equipment, the semiconductor memory device disclosed in Japanese Patent Laying-Open No. 2000-21197 includes a delay circuit internally generating a time period comparable to write command read time tRWL and precharge time tPR, and the operation test of the semiconductor memory device can be conducted with write command read time tRWL and precharge time tPR corresponding to an external /RAS signal with a duration smaller than a defined value inherent to the measuring equipment.

On the other hand, in order to prevent destruction of stored data caused by an inappropriate external RAS width setting, a DRAM provided with an RAS guarantee circuit ensuring an internal RAS width of a prescribed amount (for a prescribed period) is known. In other words, as described above, the restoring operation of the data to the memory cell is performed with the sensing operation in the DRAM. On the other hand, if the external RAS width for a short period of time is set beyond the current drivability of the access transistor in the memory cell, the restoring operation is not completed, and the stored data may be destroyed.

In order to ensure a time period required to fully complete data restoration even if the externally set, external RAS width is small, the internal RAS guarantee circuit ensures the internal RAS width for a prescribed period. If the external RAS width is larger than the prescribed period, the RAS guarantee circuit substantially does not function. Meanwhile, if the external RAS width is smaller than the prescribed period, the RAS guarantee circuit functions so as to prevent destruction of the stored data.

The RAS guarantee circuit described above is provided in order to prevent malfunction due to the small external RAS width. When a test with reduced internal RAS width is conducted, however, the RAS guarantee circuit presents an obstacle. In other words, even if the external RAS width for a short period of time is externally set in order to reduce the internal RAS width, the RAS guarantee circuit will operate, and accordingly, the internal RAS width at least for the prescribed period described above is ensured. Therefore, for the semiconductor memory device including the conventional RAS guarantee circuit, the test described above with the internal RAS width for a time period shorter than the prescribed period guaranteed by the RAS guarantee circuit cannot be conducted.

Further, the semiconductor memory device disclosed in Japanese Patent Laying-Open No. 2000-21197 relates to a semiconductor memory device in which a test with reduced write command read time tRWL and precharge time tPR is possible. In the semiconductor memory device provided with the above-described RAS guarantee circuit, however, the internal RAS width cannot be made smaller than the prescribed period defined by the RAS guarantee circuit.

In addition, the semiconductor memory device can eventually modify the internal RAS width by reducing write command read time tRWL and precharge time tPR. On the other hand, if the RAS guarantee circuit is provided, the internal RAS width cannot be modified to attain internal RAS width smaller than the above-described prescribed period, because of the operation of the RAS guarantee circuit. Therefore, this semiconductor memory device cannot solve the above-described problems.

Moreover, in the semiconductor memory device disclosed in Japanese Patent Laying-Open No. 2000-21197, an operation for data writing is tested. If the internal RAS width can directly be modified, however, an operation for data reading can also be tested.

### SUMMARY OF THE INVENTION

The present invention was made to solve the above-described problems. An object of the present invention is to provide a semiconductor memory device of which internal RAS width can externally be controlled in a test mode.

According to the present invention, a semiconductor memory device continues an access operation to a memory cell at least until a prescribed period elapses, when it receives a first control command to start access to the memory cell storing data in a normal operation mode. The semiconductor memory device includes a word line and a bit line pair connected to the memory cell, and a control circuit controlling the access operation based on a control command received from the outside. The prescribed period is a period in which restoration of the data to the memory cell is completed. The control circuit terminates control of the access operation in response to a second control command received from the outside regardless of elapse of the prescribed period, upon receiving the first control command in a test mode.

According to the present semiconductor memory device, in the normal operation mode, the internal RAS width for the prescribed period that guarantees data restoration to the memory cell is ensured, regardless of the externally set RAS width. On the other hand, in the test mode, interlock ensuring the internal RAS width for the prescribed period is released, to allow external control of the internal RAS width.

Therefore, in the normal operation mode, the internal RAS width for the prescribed period is guaranteed, while in the test mode, the internal RAS width smaller than the above-described prescribed period can externally be set. Thus, an operation margin test for eliminating a memory cell with insufficient current drivability can be conducted.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing an overall configuration of a semiconductor memory device in a first embodiment according to the present invention.

FIG. 2 is a functional block diagram showing in detail a configuration from an input buffer to a word line activation circuit in the semiconductor memory device shown in FIG. 1.

FIG. 3 is a circuit diagram showing a configuration of the input buffer shown in FIG. 2.

FIG. 4 is a circuit diagram showing a configuration of a command decoder shown in FIG. 2.

FIG. 5 is a circuit diagram showing a configuration of an internal RAS generating circuit shown in FIG. 2.

FIG. 6 is a circuit diagram showing a configuration of a word line activation signal generating circuit shown in FIG. 2.

FIG. 7 is a circuit diagram showing a configuration of an internal RAS guarantee signal generating circuit shown in FIG. 2.

FIG. 8 is a circuit diagram showing a configuration of a word line activation circuit shown in FIG. 2.

FIG. 9 is an operational waveform diagram of primary signals in the semiconductor memory device in the first embodiment when a precharge command is input before an internal RAS guarantee period elapses in a normal operation mode.

FIG. 10 is an operational waveform diagram of the primary signals in the semiconductor memory device in the first embodiment when the precharge command is input before the internal RAS guarantee period elapses in a test mode.

FIG. 11 is an operational waveform diagram of the primary signals in the semiconductor memory device in the first embodiment when the precharge command is input after the internal RAS guarantee period has elapsed in the normal operation mode.

FIG. 12 is a schematic block diagram showing an overall configuration of a semiconductor memory device in a second embodiment according to the present invention.

FIG. 13 is a functional block diagram showing in detail a configuration from the input buffer to the word line activation circuit in the semiconductor memory device shown in FIG. 12.

FIG. 14 is a circuit diagram showing a configuration of a command decoder shown in FIG. 13.

FIG. 15 is a circuit diagram showing a configuration of an internal RAS generating circuit shown in FIG. 13.

FIG. 16 is an operational waveform diagram of primary signals in the test mode in the semiconductor memory device in the second embodiment.

### DESCRIPTION OF THE PREFERRED EMBODIMENTS

In the following, embodiments of the present invention will be described in detail with reference to the figures. It is noted that the same reference characters refer to the same or corresponding components in the figures.

### First Embodiment

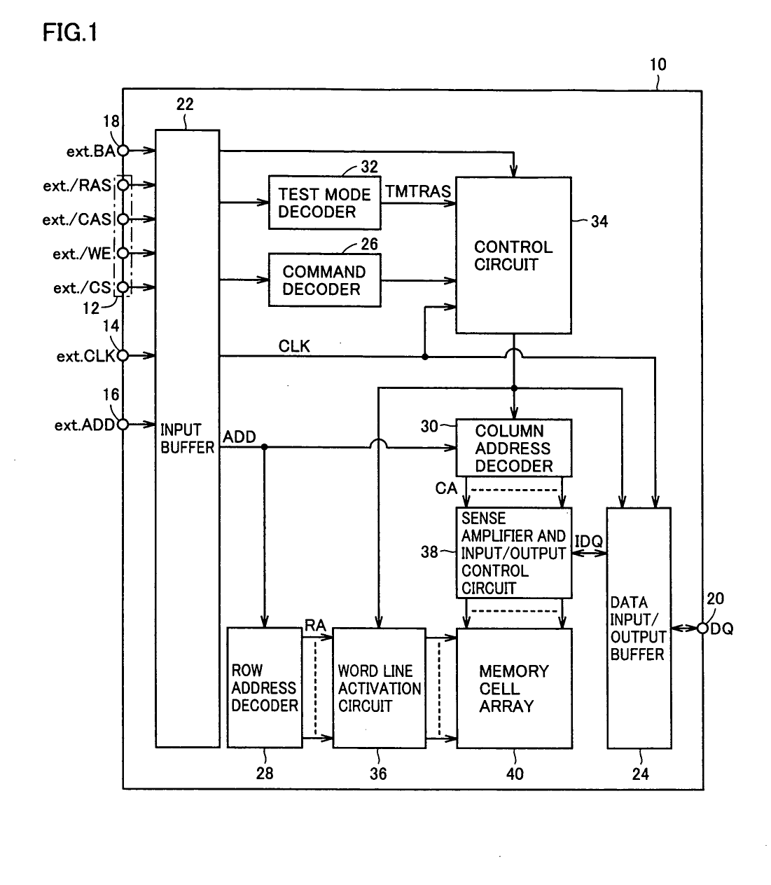

FIG. 1 is a schematic block diagram showing an overall configuration of a semiconductor memory device in a first embodiment according to the present invention.

Referring to FIG. 1, a semiconductor memory device 10 includes a control signal terminal 12, a clock terminal 14, an address terminal 16, a bank address terminal 18, and a data input/output terminal 20. In addition, semiconductor memory device 10 includes an input buffer 22, a data input/output buffer 24, a command decoder 26, a row address decoder 28, a column address decoder 30, and a test mode decoder 32. Further, semiconductor memory device 10 includes a control circuit 34, a word line activation circuit 36, a sense amplifier and input/output control circuit 38, and a memory cell array 40.

Control signal terminal 12 receives from the outside, command control signals including a row address strobe signal ext./RAS, a column address strobe signal ext./CAS, a write enable signal ext./WE, and a chip select signal ext./CS. Clock terminal 14 receives an external clock ext.CLK from the outside. Address terminal 16 receives an address signal ext.ADD from the outside. Bank address terminal 18 receives a bank address signal ext.BA from the outside.

Input buffer 22 takes in and latches command control signals including row address strobe signal ext./RAS, column address strobe signal ext./CAS, write enable signal ext./WE, and chip select signal ext./CS, as well as address signal ext.ADD and bank address signal ext.BA, in response to external clock ext.CLK, and generates an internal command control signal, an internal address signal ADD, and an internal bank address signal /BA corresponding to each signal. Further, input buffer 22 generates an internal clock CLK upon receiving external clock ext.CLK.

Input buffer 22 then outputs the internal command control signal to command decoder 26, test mode decoder 32, and control circuit 34. In addition, input buffer 22 outputs internal address signal ADD to row address decoder 28 and column address decoder 30. Moreover, input buffer 22 outputs internal clock CLK to control circuit 34 and data input/output buffer 24.

Data input/output terminal 20 communicates data read and written in semiconductor memory device 10 with the outside. Data input/output terminal 20 receives externally input data DQ in data writing, while it outputs the same to the outside in data reading.

In data writing, data input/output buffer 24 takes in and latches data DQ in response to internal clock CLK received from input buffer 22, and outputs internal data IDQ to sense amplifier and input/output control circuit 38. On the other hand, in data reading, data input/output buffer 24 outputs internal data IDQ received from sense amplifier and input/output control circuit 38 to data input/output terminal 20 in response to internal clock CLK received from input buffer 22.

Command decoder 26 generates an internal command based on the internal command control signal received from input buffer 22, and outputs the generated internal command to control circuit 34.

Row address decoder 28 receives internal address signal ADD from input buffer 22, and generates an row address signal RA for selecting a word line corresponding to a row address designated by internal address signal ADD, to output the signal to word line activation circuit 36. Column address decoder 30 receives internal address signal ADD from input buffer 22, and generates a column address signal CA for selecting a bit line pair corresponding to a column address designated by internal address signal ADD, to output the signal to sense amplifier and input/output control circuit 38.

Test mode decoder 32 receives the internal command control signal and internal address signal ADD from input buffer 22, and generates a test mode signal TMTRAS based on those signals, to output the same to control circuit 34. Here, when test mode decoder 32 determines that the operation mode for testing the operation margin of the memory cell with the reduced internal RAS width (hereinafter, simply referred to as the “test mode”) has been instructed based on the internal command control signal and internal address signal ADD, test mode decoder 32 outputs test mode signal TMTRAS at H (logic high) level. On the other hand, when not in the test mode, that is, in the normal operation mode, test mode decoder 32 outputs test mode signal TMTRAS at L (logic low) level.

Control circuit 34 receives the internal command, the internal command control signal and test mode signal TMTRAS from command decoder 26, input buffer 22, and test mode decoder 32 respectively, in response to internal clock CLK received from input buffer 22. Then, control circuit 34 controls word line activation circuit 36, column address decoder 30, and data input/output buffer 24 based on those signals. Specific configuration and operation of control circuit 34 will be described in detail later.

Word line activation circuit 36 operates based on a control command from control circuit 34, and activates the word line corresponding to row address signal RA received from row address decoder 28.

In data writing, sense amplifier and input/output control circuit 38 precharges the bit line pair corresponding to column address signal CA received from column address decoder 32 to a power supply voltage level or a ground voltage level, in accordance with a logic level of internal data IDQ received from data input/output buffer 24. Accordingly, internal data IDQ is written to the memory cell on memory cell array 40 connected to the word line activated by word line activation circuit 36, and the bit line pair selected by column address decoder 30 and precharged by sense amplifier and input/output control circuit 38.

Meanwhile, in data reading, sense amplifier and input/output control circuit 38 precharges the bit line pair selected by column address decoder 30 before data reading, detects/amplifies small voltage change produced corresponding to the read data in the selected bit line pair to determine the logic level of the read data, and outputs the determination result to data input/output buffer 24.

Memory cell array 40 is a group of memory elements, that is, formed with memory cells arranged in matrix. Memory cell array 40 is connected to word line activation circuit 36 through the word line corresponding to each row, and also connected to sense amplifier and input/output control circuit 38 through the bit line pair corresponding to each column.

Semiconductor memory device 10 can take the normal operation mode and the above-described test mode as an operation mode. In the normal operation mode, control circuit 34 secures the internal RAS width at least for a prescribed period in order to ensure a time period required to fully complete data restoration, even if the externally set external RAS width is small. In other words, even if the precharge command is externally input during the prescribed period, control circuit 34 continues to activate word line activation circuit 36 until the prescribed period elapses. That is, word line activation circuit 36 continues to activate the word line until the prescribed period elapses.

On the other hand, in the test mode, control circuit 34 releases the interlock ensuring the internal RAS width for the prescribed period. This is for allowing the operation margin test of the memory cell with the reduced internal RAS width, as described above. Therefore, in the test mode, control circuit 34 inactivates word line activation circuit 36 at a timing when the precharge command is externally input, and word line activation circuit 36 inactivates the word line in response to the command from control circuit 34.

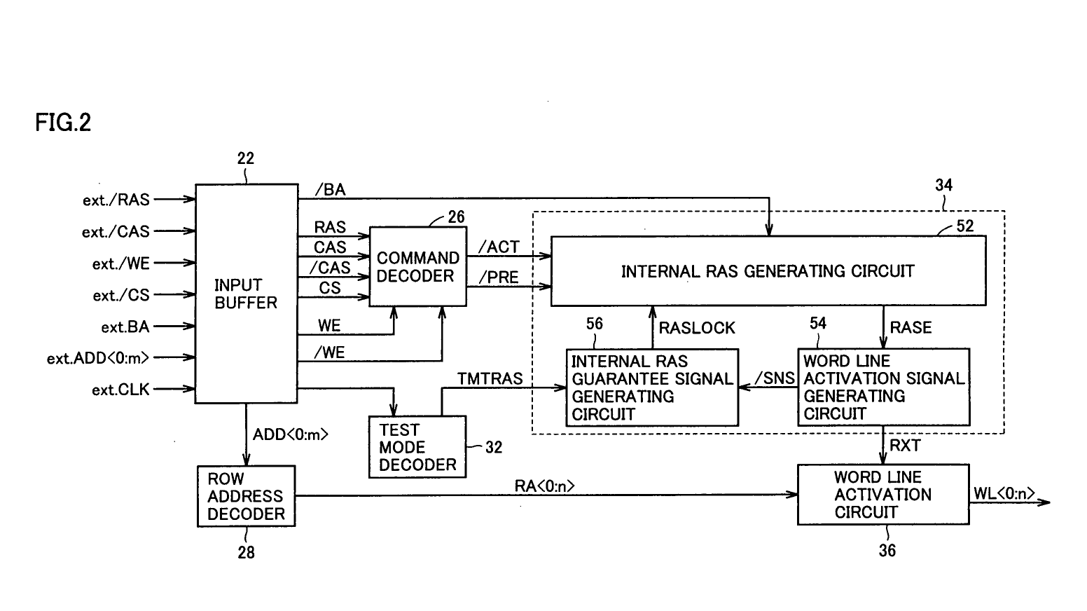

FIG. 2 is a functional block diagram showing in detail a configuration from input buffer 22 to word line activation circuit 36 in semiconductor memory device 10 shown in FIG. 1. In the following, description for components also found in FIG. 1 will not be repeated.

Referring to FIG. 2, input buffer 22 outputs an internal row address strobe signal RAS, internal column address strobe signals CAS, /CAS, an internal chip select signal CS, and internal write enable signals WE, /WE to command decoder 26. In addition, input buffer 22 outputs an internal bank address signal /BA to an internal RAS generating circuit 52 described later, and outputs an internal address signal ADD<0:m> (m is a natural number) to row address decoder 28. Further, input buffer 22 outputs the above-mentioned internal command control signal and a prescribed internal address signal ADD<i> (i is a prescribed, natural number) also to test mode decoder 32.

Command decoder 26 generates an active signal /ACT and a precharge signal /PRE based on each signal received from input buffer 22, and outputs each generated signal to internal RAS generating circuit 52.

Control circuit 34 includes internal RAS generating circuit 52, a word line activation signal generating circuit 54, and an internal RAS guarantee signal generating circuit 56.

Internal RAS generating circuit 52 receives active signal /ACT, precharge signal /PRE, internal bank address signal /BA, and an internal RAS guarantee signal RASLOCK, generates an internal signal RASE instructing activation of the word line based on those signals, and outputs generated internal signal RASE to word line activation signal generating circuit 54.

Internal RAS generating circuit 52 outputs internal signal RASE at H level, upon receiving active signal /ACT when internal bank address signal /BA is at L level. Internal RAS generating circuit 52 outputs internal signal RASE at H level, at least during a period in which internal RAS guarantee signal RASLOCK output from internal RAS guarantee signal generating circuit 56 is at L level. In other words, internal RAS guarantee signal RASLOCK guarantees a minimum internal RAS width. While this signal is asserted (L level), internal RAS generating circuit 52 holds internal signal RASE at H level, even if it receives precharge signal /PRE instructing inactivation of the word line.

On the other hand, when internal RAS guarantee signal RASLOCK is at H level, internal RAS generating circuit 52 sets internal signal RASE to L level at a timing when precharge signal /PRE is accepted.

Upon receiving internal signal RASE from internal RAS generating circuit 52, word line activation signal generating circuit 54 outputs a word line activation signal RXT at H level when internal signal RASE is at H level, to activate word line activation circuit 36. In addition, word line activation signal generating circuit 54 outputs an internal signal /SNS at L level to internal RAS guarantee signal generating circuit 56 in response to internal signal RASE, to notify internal RAS guarantee signal generating circuit 56 of instruction of activation of the word line.

Internal RAS guarantee signal generating circuit 56, upon receiving test mode signal TMTRAS and internal signal /SNS, outputs internal RAS guarantee signal RASLOCK at L level when test mode signal TMTRAS is at L level, that is, in the normal operation mode, in response to internal signal /SNS, to negate (H level) internal RAS guarantee signal RASLOCK after the internal RAS guarantee period counted internally has elapsed.

On the other hand, internal RAS guarantee signal generating circuit 56 holds internal RAS guarantee signal RASLOCK at H level regardless of internal signal /SNS indicating instruction of activation of the word line, when test mode signal TMTRAS is at H level, that is, in the test mode. In other words, in the test mode, internal RAS guarantee signal generating circuit 56 does not assert (L level) internal RAS guarantee signal RASLOCK which is an interlock signal for guaranteeing the internal RAS width.

Word line activation circuit 36 activates a word line <0:n> designated by a row address signal RA<0:n> received from row address decoder 28, in response to word line activation signal RXT.

Here, internal RAS generating circuit 52 constitutes an “internal signal generating circuit,” while internal RAS guarantee signal generating circuit 56 constitutes a “guarantee signal generating circuit.”

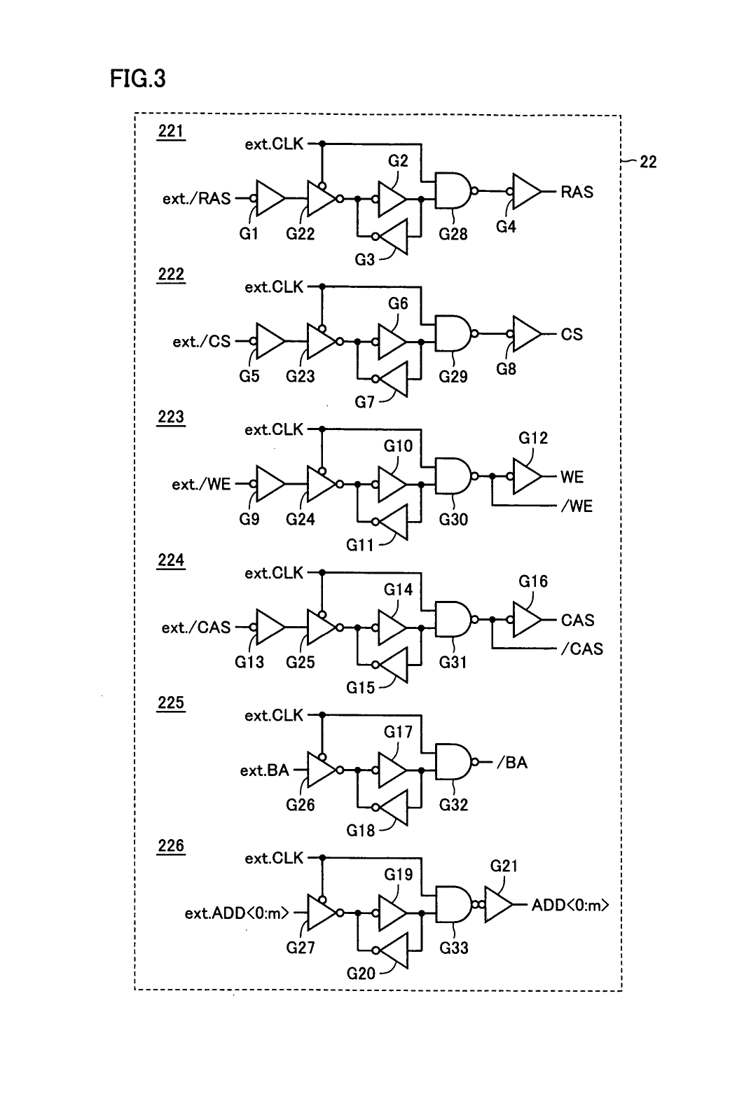

FIG. 3 is a circuit diagram showing a configuration of input buffer 22 shown in FIG. 2.

Referring to FIG. 3, input buffer 22 includes circuits 221 to 226. Circuit 221 includes inverters G1 to G4, a clocked inverter G22, and an NAND gate G28, while circuit 222 includes inverters G5 to G8, a clocked inverter G23, and an NAND gate G29. Circuit 223 includes inverters G9 to G12, a clocked inverter G24, and an NAND gate G30, while circuit 224 includes inverters G13 to G16, a clocked inverter G25, and an NAND gate G31. Circuit 225 includes inverters G17, G18, a clocked inverter G26, and an NAND gate G32, while circuit 226 includes inverters G19 to G21, a clocked inverter G27, and an NAND gate G33.

In circuit 221, inverter G1 outputs an inverted signal of row address strobe signal ext./RAS. Clocked inverter G22 outputs a signal obtained by inverting an output signal from inverter G1, when external clock ext.CLK is at H level. Inverter G2 outputs a signal obtained by inverting an output signal from clocked inverter G22, while inverter G3 outputs a signal obtained by inverting an output signal from inverter G2. Inverters G2, G3 constitute a latch circuit.

NAND gate G28 performs AND operation of the output signal from inverter G2 and external clock ext.CLK, and outputs a signal obtained by inverting the operation result. Inverter G4 outputs a signal obtained by inverting an output signal from NAND gate G28 as internal row address strobe signal RAS.

When external clock ext.CLK is at H level, circuit 221 takes in row address strobe signal ext./RAS, and outputs internal row address strobe signal RAS.

Circuits 222 to 224 are configured in a manner similar to circuit 221. When external clock ext.CLK is at H level, circuit 222 takes in chip select signal ext./CS, and outputs internal chip select signal CS. When external clock ext.CLK is at H level, circuit 223 takes in write enable signal ext./WE, and outputs internal write enable signals WE, /WE. When external clock ext.CLK is at H level, circuit 224 takes in column address strobe signal ext./CAS, and outputs internal column address strobe signals CAS, /CAS.

In circuit 225, when external clock ext.CLK is at H level, clocked inverter G26 outputs an inverted signal of bank address signal ext.BA. Inverters G17, G18 constitute a latch circuit. NAND gate G32 performs AND operation of the output signal from inverter G17 and external clock ext.CLK, and outputs a signal obtained by inverting the operation result as internal bank address signal /BA.

When external clock ext.CLK is at H level, circuit 225 takes in bank address signal ext.BA, and outputs internal bank address signal /BA.

In circuit 226, when external clock ext.CLK is at H level, clocked inverter G27 outputs an inverted signal of address signal ext.ADD<0:m>. Inverters G19, G20 constitute a latch circuit. NAND gate G33 performs AND operation of the output signal from inverter G19 and external clock ext.CLK, and outputs a signal obtained by inverting the operation result. Inverter G21 outputs a signal obtained by inverting an output signal from NAND gate G33 as internal address signal ADD<0:m>.

When external clock ext.CLK is at H level, circuit 226 takes in address signal ext.ADD<0:m>, and outputs internal address signal ADD<0:m>.

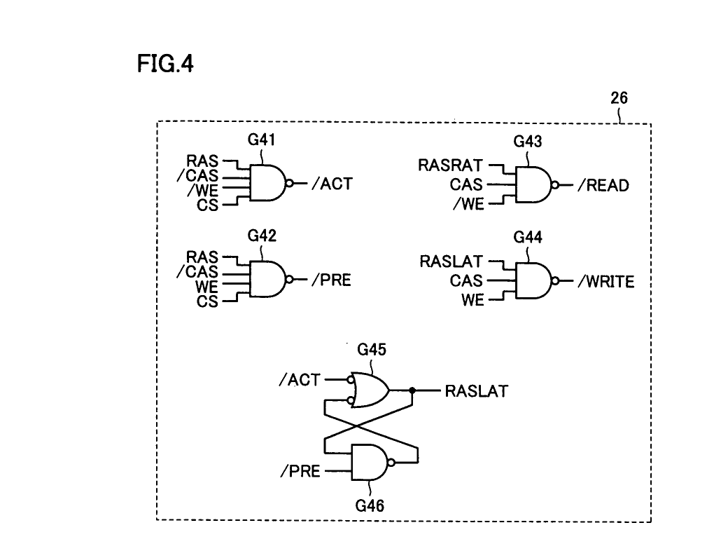

FIG. 4 is a circuit diagram showing a configuration of command decoder 26 shown in FIG. 2.

Referring to FIG. 4, command decoder 26 includes NAND gates G41 to G46. NAND gate G41 performs AND operation of internal row address strobe signal RAS, internal column address strobe signal /CAS, internal write enable signal /WE, and internal chip select signal CS, and outputs a signal obtained by inverting the operation result as active signal /ACT. NAND gate G42 performs AND operation of internal row address strobe signal RAS, internal column address strobe signal /CAS, internal write enable signal WE, and internal chip select signal CS, and outputs a signal obtained by inverting the operation result as precharge signal /PRE.

NAND gate G43 performs AND operation of an internal signal RASLAT described later, internal column address strobe signal CAS, and internal write enable signal /WE, and outputs a signal obtained by inverting the operation result as a read signal /READ. NAND gate G44 performs AND operation of internal signal RASLAT, internal column address strobe signal CAS, and internal write enable signal WE, and outputs a signal obtained by inverting the operation result as a write signal /WRITE.

NAND gate G45 performs AND operation of active signal /ACT and an output signal from NAND gate G46, and outputs a signal obtained by inverting the operation result as internal signal RASLAT. NAND gate G46 performs AND operation of precharge signal /PRE and an output signal from NAND gate G45, and outputs a signal obtained by inverting the operation result to NAND gate G45.

NAND gates G45, G46 constitute an RS flip-flop circuit. That is, when active signal /ACT as a set input attains L level, the flip-flop circuit enters a set state, and internal signal RASLAT attains H level. Then, when precharge signal /PRE as a reset input attains L level, the flip-flop circuit enters a reset state, and internal signal RASLAT attains L level.

Command decoder 26 asserts (L level) active signal /ACT, when internal row address strobe signal RAS, internal column address strobe signal CAS, internal write enable signal WE, and internal chip select signal CS attain H level, L level, L level and H level respectively.

In addition, command decoder 26 asserts (L level) precharge signal /PRE, when internal row address strobe signal RAS, internal column address strobe signal CAS, internal write enable signal WE, and internal chip select signal CS attain H level, L level, H level and H level respectively.

Further, command decoder 26 asserts (L level) read signal /READ when internal column address strobe signal CAS and internal write enable signal WE attain H level and L level respectively, from a time point when active signal /ACT attains L level to a time point when precharge signal /PRE attains L level, that is, during a row activation period.

Moreover, command decoder 26 asserts (L level) write signal /WRITE when internal column address strobe signal CAS and internal write enable signal WE both attain H level during the above-mentioned row activation period.

FIG. 5 is a circuit diagram showing a configuration of internal RAS generating circuit 52 shown in FIG. 2.

Referring to FIG. 5, internal RAS generating circuit 52 includes NOR gates G51 to G53, NAND gates G54 to G56, and inverters G57 to G59. NOR gate G51 performs OR operation of active signal /ACT and internal bank address signal /BA, and outputs a signal obtained by inverting the operation result. NOR gate G52 performs OR operation of precharge signal /PRE and internal bank address signal /BA, and outputs a signal obtained by inverting the operation result.

Inverter G57 outputs a signal obtained by inverting an output signal from NOR gate G51, and inverter G58 outputs a signal obtained by inverting an output signal from NOR gate G52. NAND gate G54 performs AND operation of output signals from inverter G57 and NAND gate G55, and outputs a signal obtained by inverting the operation result. NAND gate G55 performs AND operation of output signals from inverter G58 and NAND gate G54, and outputs a signal obtained by inverting the operation result.

NAND gates G56 performs AND operation of the output signal from NAND gate G55 and internal RAS guarantee signal RASLOCK output from internal RAS guarantee signal generating circuit 56, and outputs a signal obtained by inverting the operation result. NOR gate G53 performs OR operation of output signals from NAND gates G51 and G56, and outputs a signal obtained by inverting the operation result. Inverter G59 inverts an output signal from NOR gate G53, and outputs the inverted signal as internal signal RASE.

In internal RAS generating circuit 52, NOR gates G51, G52, inverters G57, G58, and NAND gates G54, G55 constitute a flip-flop circuit having active signal /ACT and precharge signal /PRE as a set input and a reset input respectively. When active signal /ACT attains L level while internal bank address signal /BA is at L level, the flip-flop circuit enters the set state, and internal RAS generating circuit 52 outputs internal signal RASE at H level.

Here, when internal RAS guarantee signal RASLOCK is at H level, an output of the flip-flop circuit is reflected to NOR gate G53 through NAND gate G56. Therefore, in this case, when precharge signal /PRE attains L level, the flip-flop circuit is reset, and accordingly, internal signal RASE attains L level.

On the other hand, when internal RAS guarantee signal RASLOCK is at L level, an output of NAND gate G56 attains H level regardless of the logic level of the output signal from NAND gate G55, and internal signal RASE attains H level. Therefore, in this case, even if precharge signal /PRE attains L level, internal signal RASE is not set to L level. Subsequently, in response to internal RAS guarantee signal RASLOCK attaining H level, internal signal RASE attains L level.

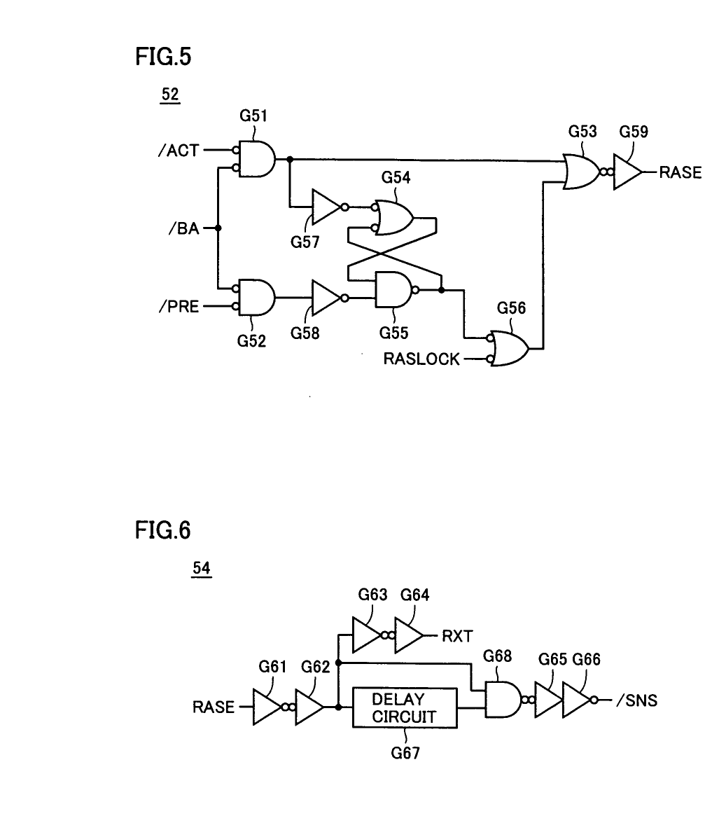

FIG. 6 is a circuit diagram showing a configuration of word line activation signal generating circuit 54 shown in FIG. 2.

Referring to FIG. 6, word line activation signal generating circuit 54 includes inverters G61 to G66, a delay circuit G67, and an NAND gate G68. Inverter G61 outputs an inverted signal of internal signal RASE received from internal RAS generating circuit 52, while inverter G62 outputs a signal obtained by inverting the output signal from inverter G61. Inverter G63 outputs a signal obtained by inverting the output signal from inverter G62, while inverter G64 inverts an output signal from inverter G63, and outputs the inverted signal as word line activation signal RXT.

Delay circuit G67 is constituted with inverters connected in series and having an even number of stages, and outputs a signal delayed by a prescribed delay time Td1 with respect to the output signal from inverter G62. NAND gate G68 performs AND operation of output signals from inverter G62 and delay circuit G67, and outputs a signal obtained by inverting the operation result. Inverter G65 outputs a signal obtained by inverting the output signal from NAND gate G68, and inverter G66 outputs a signal obtained by inverting the output signal from inverter G65 as internal signal /SNS.

A circuit constituted with delay circuit G67, NAND gate G68, and inverter G65 generates a signal obtained by delaying the rising edge of the output signal from inverter G62 by delay time Td1.

Word line activation signal generating circuit 54 outputs word line activation signal RXT at H level, when internal signal RASE attains H level. Then, word line activation signal generating circuit 54 sets internal signal /SNS from H level to L level, after delay time Td1 has elapsed since the rise of internal signal RASE.

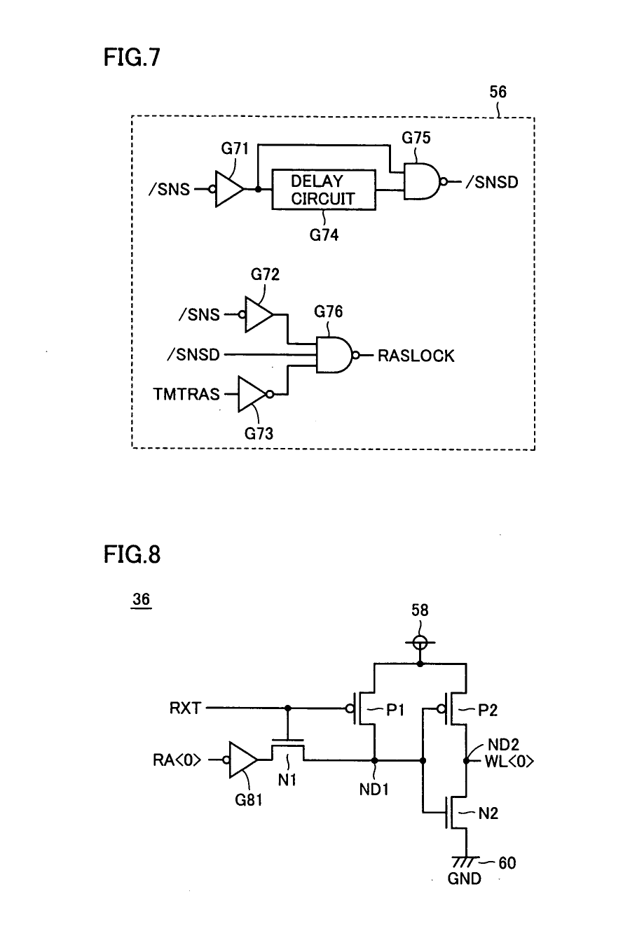

FIG. 7 is a circuit diagram showing a configuration of internal RAS guarantee signal generating circuit 56 shown in FIG. 2.

Referring to FIG. 7, internal RAS guarantee signal generating circuit 56 includes inverters G71 to G73, a delay circuit G74, and NAND gates G75, G76. Inverter G71 outputs an inverted signal of internal signal /SNS. Delay circuit G74 is constituted with inverters connected in series and having an even number of stages, and outputs a signal delayed by a prescribed delay time Td2 with respect to the output signal from inverter G71. NAND gate G75 performs AND operation of output signals from inverter G71 and delay circuit G74, and outputs a signal obtained by inverting the operation result as an internal signal /SNSD.

Inverter G72 outputs an inverted signal of internal signal /SNS. Inverter G73 outputs an inverted signal of test mode signal TMTRAS output from test mode decoder 32 shown in FIG. 2. NAND gate G76 performs AND operation of output signals from inverters G72, G73 and internal signal /SNSD, and outputs a signal obtained by inverting the operation result as internal RAS guarantee signal RASLOCK.

A circuit constituted with inverter G71, delay circuit G74, and NAND gate G75 generates internal signal /SNSD obtained by delaying the falling edge of internal signal /SNS by delay time Td2.

A circuit constituted with inverters G72, G73, and NAND gate G76 outputs internal RAS guarantee signal RASLOCK at H level regardless of the logic level of internal signals /SNS, /SNSD, when test mode signal TMTRAS is at H level. In other words, the interlock ensuring the internal RAS width for the prescribed period is not set. On the other hand, when test mode signal TMTRAS is at L level, the circuit above sets internal RAS guarantee signal RASLOCK to L level in response to internal signal /SNS attaining L level, and sets internal RAS guarantee signal RASLOCK to H level in response to internal signal /SNSD attaining L level after delay time Td2 since the fall of internal signal /SNS. In other words, delay time Td2 by delay circuit G74 will be the internal RAS guarantee period.

Here, the circuit constituted with inverters G72, G73, and NAND gate G76 forms an “output circuit” in the “guarantee signal generating circuit.”

FIG. 8 is a circuit diagram showing a configuration of word line activation circuit 36 shown in FIG. 2. Word line activation circuit 36 includes n word line drivers corresponding to row address signals RA<0:n>. Each word line driver, however, has a similar configuration, and therefore, FIG. 8 shows solely a circuit corresponding to row address signal RA<0>.

Referring to FIG. 8, word line activation circuit 36 includes P-channel MOS transistors P1, P2, N-channel MOS transistors N1, N2, and an inverter G81. Inverter G81 outputs an inverted signal of row address signal RA<0>. N-channel MOS transistor N1 is connected between an output node of inverter G81 and a node ND1, and receives word line activation signal RXT at its gate. P-channel MOS transistor P1 is connected between a power supply node 58 and node ND1, and receives word line activation signal RXT at its gate.

In addition, P-channel MOS transistor P2 is connected between power supply node 58 and an output node ND2, and has the gate connected to node ND1. N-channel MOS transistor N2 is connected between node ND2 and a ground node 60, and has the gate connected to node ND1.

In word line activation circuit 36, when word line activation signal RXT is at H level, N-channel MOS transistor N1 turns ON, and P-channel MOS transistor P1 turns OFF. Therefore, a word line WL<0> connected to output node ND2 is driven by a drive unit constituted with P-channel MOS transistor P2 and N-channel MOS transistor N2, in accordance with the logic level of row address signal RA<0>0 transmitted to node ND1.

On the other hand, when word line activation signal RXT is at L level, N-channel MOS transistor N1 turns OFF, and P-channel MOS transistor P1 turns ON. Therefore, node ND1 attains H level and output node ND2 attains L level, regardless of row address signal RA<0>. In other words, when word line activation signal RXT is at L level, word line activation circuit 36 is inactivated.

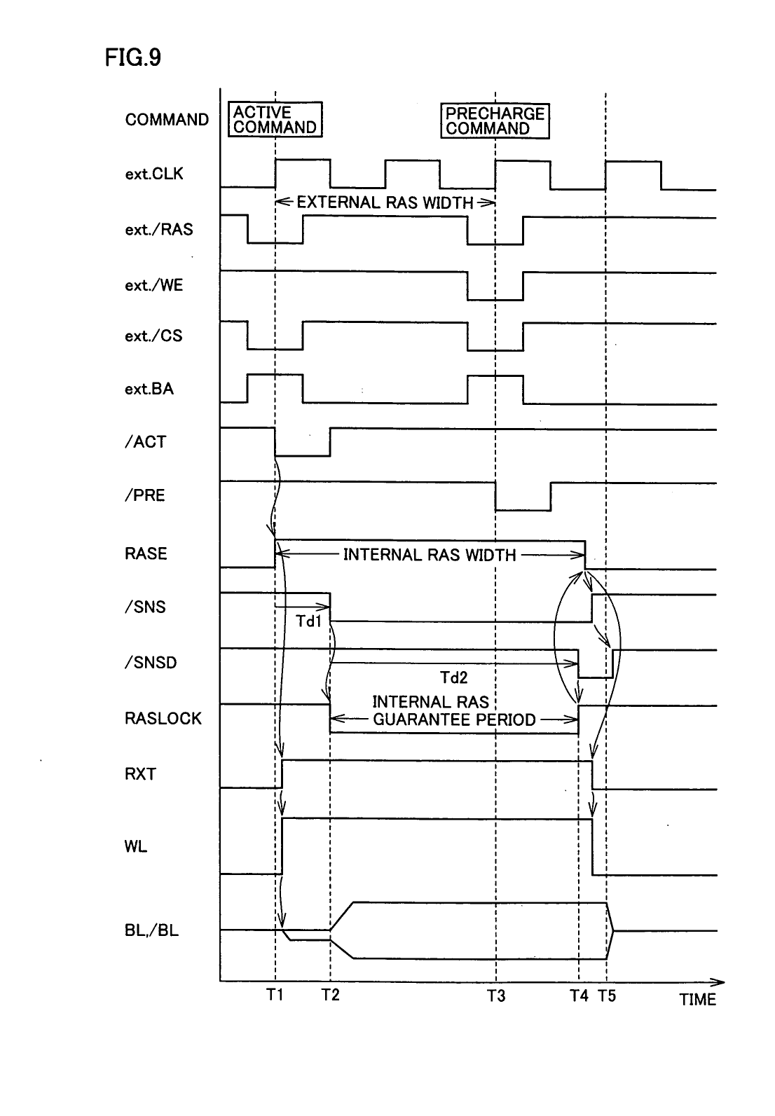

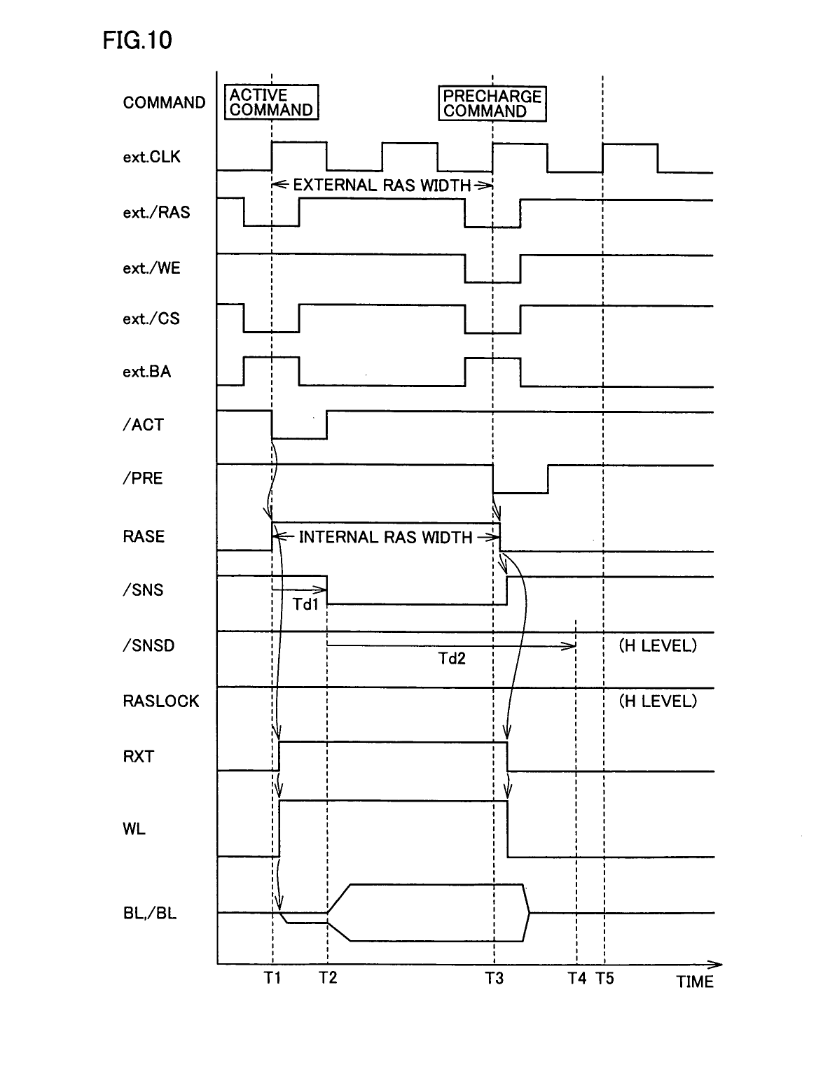

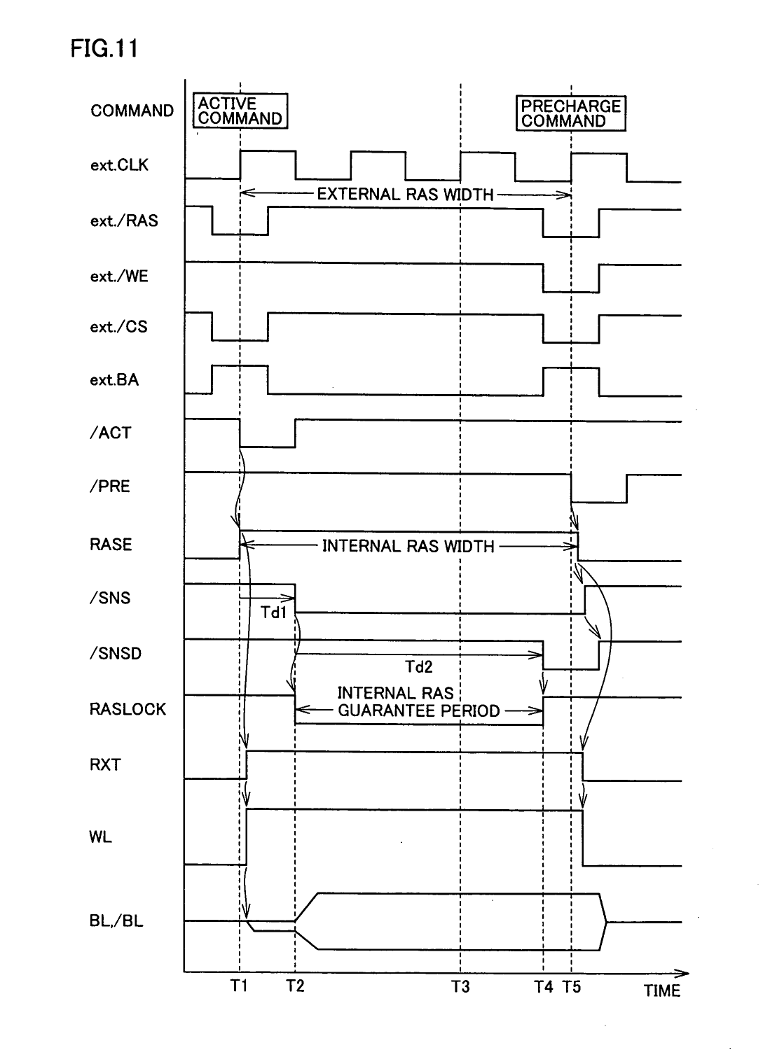

FIGS. 9 to 11 are operational waveform diagrams of primary signals in semiconductor memory device 10 in the first embodiment. FIG. 9 is an operational waveform diagram when a precharge command is input before the internal RAS guarantee period elapses in the normal operation mode; FIG. 10 is an operational waveform diagram when the precharge command is input before the internal RAS guarantee period elapses in the test mode; and FIG. 11 is an operational waveform diagram when the precharge command is input after the internal RAS guarantee period has elapsed in the normal operation mode.

Referring to FIG. 9, though not shown, test mode signal TMTRAS is always at L level, and the normal operation mode is designated. When external clock ext.CLK rises at time T1 in a state where row address strobe signal ext./RAS, write enable signal ext./WE, chip select signal ext./CS and not-shown column address strobe signal ext./CAS attain L level, H level, L level, and H level respectively, and bank address signal ext.BA attains H level, command decoder 26 sets active signal /ACT to L level.

In response to this, internal RAS generating circuit 52 sets internal signal RASE to H level, while word line activation signal generating circuit 54 sets word line activation signal RXT to H level, and sets internal signal /SNS to L level after delay time Td1 has elapsed. In response to word line activation signal RXT, word line activation circuit 36 activates word line WL indicated by internal row address signal <0:n>, to initiate data reading to bit line pair BL, /BL.

When internal signal /SNS attains L level at time T2, internal RAS guarantee signal generating circuit 56 sets internal RAS guarantee signal RASLOCK to L level, and maintains L level during delay time Td2 by delay circuit G74.

When external clock ext.CLK rises at time T3 in a state where row address strobe signal ext./RAS, write enable signal ext./WE, chip select signal ext./CS, and not-shown column address strobe signal ext./CAS attain L level, L level, L level, and H level respectively, and bank address signal ext.BA attains H level, command decoder 26 sets precharge signal /PRE to L level.

Here, time T3 when precharge signal /PRE attains L level in response to the precharge command is within the internal RAS guarantee period, and internal RAS guarantee signal RASLOCK is at L level. Therefore, internal RAS generating circuit 52 does not set internal signal RASE to L level, even if precharge signal /PRE attains L level.

Internal RAS guarantee signal generating circuit 56 sets internal signal /SNSD to L level at time T4 when delay time Td2 has elapsed since time T2. In response to this, internal RAS guarantee signal generating circuit 56 sets internal RAS guarantee signal RASLOCK to H level. Then, internal RAS generating circuit 52 sets internal signal RASE to L level, and word line activation signal generating circuit 54 sets word line activation signal RXT to L level. In response to this, word line activation circuit 36 inactivates the word line that has been activated.

In this manner, in the normal operation mode, the word line is not inactivated immediately responding to reception of the precharge command within the internal RAS guarantee period. Instead, the word line is inactivated after the internal RAS guarantee period sufficient to assure the restoring operation to the memory cell has elapsed.

Referring to FIG. 10, though not shown, test mode signal TMTRAS is always at H level, and the test mode is designated. The operation at time T1 is the same as in the normal operation mode.

When internal signal /SNS falls at time T2, internal RAS guarantee signal generating circuit 56 does not set internal RAS guarantee signal RASLOCK to L level, because test mode signal TMTRAS is at H level, though it would set internal RAS guarantee signal RASLOCK to L level in the normal operation mode in which test mode signal TMTRAS is at L level.

When external clock ext.CLK rises at time T3 in a state where row address strobe signal ext./RAS, write enable signal ext./WE, chip select signal ext./CS, and not-shown column address strobe signal ext./CAS attain L level, L level, L level, and H level respectively, and bank address signal ext.BA attains H level, command decoder 26 sets precharge signal /PRE to L level.

Then, as internal RAS guarantee signal RASLOCK is at H level, internal RAS generating circuit 52 sets internal signal RASE to L level, and in response to this, word line activation signal generating circuit 54 sets word line activation signal RXT to L level. Word line activation circuit 36 then inactivates the word line that has been activated.

In this manner, in the test mode, even if the external RAS width (a period from the input of the active command to the input of the precharge command) is small, the word line is inactivated in response to the externally input precharge command. In other words, the internal RAS width can externally be controlled in semiconductor memory device 10.

Referring to FIG. 11, though not shown, test mode signal TMTRAS is always at L level, and the normal operation mode is designated. The operations at time T1, T2 are the same as those shown in FIG. 9.

At time T4 before the precharge command is received from the outside at time T5, when delay time Td2 by delay circuit G74 in internal RAS guarantee signal generating circuit 56 elapses, internal RAS guarantee signal generating circuit 56 sets internal signal /SNSD to L level, and in response to this, sets internal RAS guarantee signal RASLOCK to H level.

When external clock ext.CLK rises at time T5 in a state where row address strobe signal ext./RAS, write enable signal ext./WE, chip select signal ext./CS, and not-shown column address strobe signal ext./CAS attain L level, L level, L level, and H level respectively, and bank address signal ext.BA attains H level, command decoder 26 sets precharge signal /PRE to L level.

Then, as internal RAS guarantee signal RASLOCK has already attained H level, internal RAS generating circuit 52 sets internal signal RASE to L level, and in response to this, word line activation signal generating circuit 54 sets word line activation signal RXT to L level. Word line activation circuit 36 then inactivates the word line that has been activated.

In this manner, when the precharge command is received after the internal RAS guarantee period has elapsed, internal RAS guarantee signal generating circuit 56 does not substantially function, and the word line is inactivated by the precharge command received from the outside.

As described above, according to semiconductor memory device 10 in the first embodiment, even if a guarantee circuit (internal RAS guarantee signal generating circuit) guaranteeing the internal RAS width for the prescribed period is provided, the interlock for assuring the internal RAS width for the prescribed period is released in the test mode. Therefore, the internal RAS width is controlled by the precharge command received from the outside, without being affected by the interlock which would impose constraints during the test.

Therefore, in the normal operation mode, the internal RAS width for the prescribed period is guaranteed, while in the test mode, the internal RAS width smaller than the above-described prescribed period can externally be set. Thus, an operation margin test for eliminating a memory cell with insufficient current drivability can be conducted.

### Second Embodiment

In the first embodiment, the internal RAS width can be controlled by the precharge command. If an operation frequency of the measuring equipment is low, however, this will impose constraints, that is, the internal RAS width cannot be set smaller. In other words, the internal RAS width that can be set suffers from constraints of a maximum operation frequency of the measuring equipment.

In the second embodiment, the internal RAS width is controlled by a falling width of row address strobe signal ext./RAS which is asynchronous to external clock ext.CLK. In this manner, the measuring equipment with the low operation frequency could conduct the operation margin test with the reduced internal RAS width.

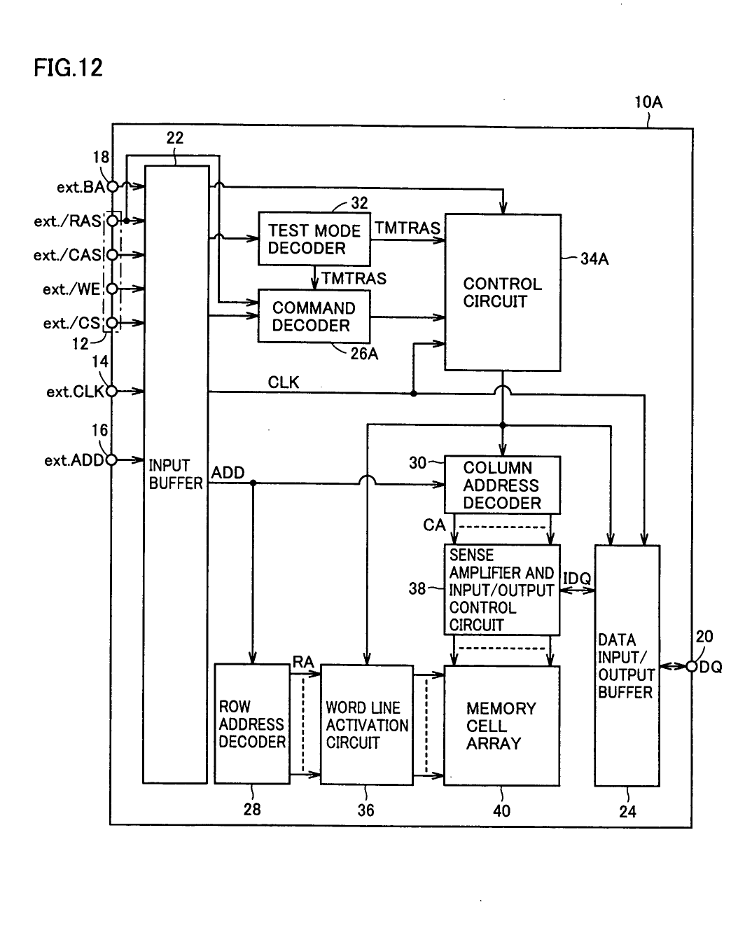

FIG. 12 is a schematic block diagram showing an overall configuration of a semiconductor memory device in a second embodiment according to the present invention.

Referring to FIG. 12, a semiconductor memory device 10A includes a command decoder 26A and a control circuit 34A respectively, instead of command decoder 26 and control circuit 34 in the configuration of semiconductor memory device 10 in the first embodiment.

Command decoder 26A receives the internal command control signal from input buffer 22, further receives row address strobe signal ext./RAS from control signal terminal 12, and receives test mode signal TMTRAS from test mode decoder 32. Command decoder 26A generates an internal command based on these signals, and outputs the generated internal command to control circuit 34A.

Control circuit 34A takes in the internal command, the internal command control signal, and test mode signal TMTRAS from command decoder 26A, input buffer 22, and test mode decoder 32 respectively, in response to internal clock CLK received from input buffer 22. Then, control circuit 34A controls word line activation circuit 36, column address decoder 30, and data input/output buffer 24 based on those signals. Specific configuration and operation of control circuit 34A will be described in detail later.

Semiconductor memory device 10A is otherwise configured in a manner similar to semiconductor memory device 10 in the first embodiment. Similar to semiconductor memory device 10, semiconductor memory device 10A can also take the normal operation mode and the test mode as the operation mode. The operation in the normal operation mode is the same as that in semiconductor memory device 10.

On the other hand, in the test mode, control circuit 34A releases the interlock ensuring the internal RAS width for the prescribed period. Though control circuit 34 in the first embodiment inactivates word line activation circuit 36 at a timing of input of the precharge command from the outside, control circuit 34A in the second embodiment inactivates the same at a timing of rise of row address strobe signal ext./RAS that fell in response to the input of the active command.

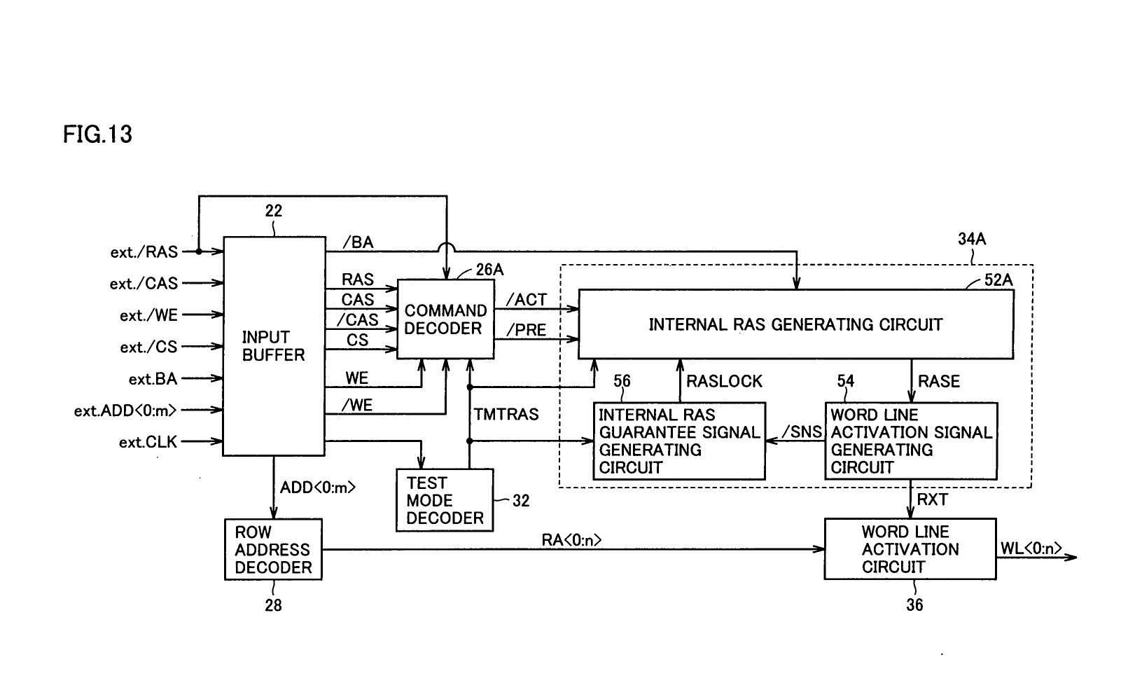

FIG. 13 is a functional block diagram showing in detail a configuration from input buffer 22 to word line activation circuit 36 in semiconductor memory device 10A shown in FIG. 12.

Referring to FIG. 13, command decoder 26A receives internal row address strobe signal RAS, internal column address strobe signals CAS, /CAS, internal chip select signal CS, and internal write enable signals WE, /WE from input buffer 22. In addition, command decoder 26A receives row address strobe signal ext./RAS from not-shown control signal terminal 12, and test mode signal TMTRAS from test mode decoder 32.

When test mode signal TMTRAS is at L level, that is, in the normal operation mode, command decoder 26A generates active signal /ACT and precharge signal /PRE based on each signal received from input buffer 22, and outputs each generated signal to an internal RAS generating circuit 52A.

When test mode signal TMTRAS is at H level, that is, in the test mode, command decoder 26A generates active signal /ACT at the timing the same as in the normal operation mode. On the other hand, command decoder 26A generates precharge signal /PRE at the timing of rise of row address strobe signal ext./RAS, not at the timing of reception of the precharge command from the outside.

Control circuit 34A includes internal RAS generating circuit 52A instead of internal RAS generating circuit 52 in the configuration of control circuit 34 in the first embodiment.

Internal RAS generating circuit 52A generates internal signal RASE based on active signal /ACT, precharge signal /PRE, internal bank address signal /BA, internal RAS guarantee signal RASLOCK, and test mode signal TMTRAS, and outputs generated internal signal RASE to word line activation signal generating circuit 54.

Internal RAS generating circuit 52A is different from internal RAS generating circuit 52 in the first embodiment in that it receives test mode signal TMTRAS. In other words, in internal RAS generating circuit 52A as well as in internal RAS generating circuit 52, internal bank address signal /BA corresponding to bank address signal ext.BA received from the outside in synchronization with external clock ext.CLK should essentially be asserted (L level) as the interlock for accepting precharge signal /PRE. In contrast, in the second embodiment, precharge signal /PRE is asserted (L level) at the timing of the rise of row address strobe signal ext./RAS, asynchronously to external clock ext.CLK. Accordingly, at that timing, internal bank address signal /BA may not be asserted (L level). Therefore, the interlock for accepting precharge signal /PRE by internal bank address signal /BA should be released.

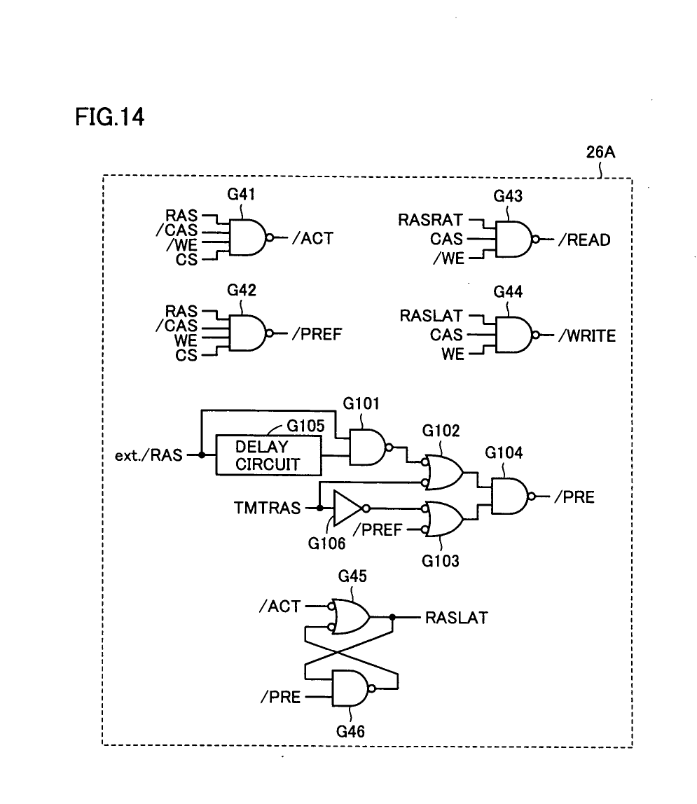

FIG. 14 is a circuit diagram showing a configuration of command decoder 26A shown in FIG. 13.

Referring to FIG. 14, command decoder 26A further includes NAND gates G101 to G104, a delay circuit G105, and an inverter G106, in addition to components in the configuration of command decoder 26 in the first embodiment. NAND gate G42 outputs an internal signal /PREF instead of precharge signal /PRE.

Delay circuit G105 is constituted with inverters connected in series and having an odd number of stages, and outputs a signal delayed by a prescribed delay time Td3 with respect to row address strobe signal ext./RAS. NAND gate G101 performs AND operation of row address strobe signal ext./RAS and an output signal from delay circuit G105, and outputs a signal obtained by inverting the operation result. A circuit constituted with delay circuit G105 and NAND gate G101 generates a falling pulse signal with a falling width of delay time Td3, at a timing of the rise of row address strobe signal ext./RAS.

Inverter G106 outputs an inverted signal of test mode signal TMTRAS. NAND gate G102 performs AND operation of an output signal from NAND G101 and test mode signal TMTRAS, and outputs a signal obtained by inverting the operation result. NAND gate G103 performs AND operation of an output signal from inverter G106 and internal signal /PREF, and outputs a signal obtained by inverting the operation result. NAND gate G104 performs AND operation of output signals from NAND gates G102, G103, and outputs a signal obtained by inverting the operation result as precharge signal /PRE.

A circuit constituted with NAND gates G101 to G104, delay circuit G105, and inverter G106 outputs internal signal /PREF output from NAND gate G42 as precharge signal /PRE, when test mode signal TMTRAS is at L level. Therefore, in the normal operation mode, command decoder 26A operates in a manner similar to command decoder 26 in the first embodiment.

On the other hand, when test mode signal TMTRAS is at H level, the aforementioned circuit outputs precharge signal /PRE having a falling width of delay time Td3, at the timing of rise of row address strobe signal ext./RAS.

Circuit configuration and operation of command decoder 26A are otherwise the same as those of command decoder 26 in the first embodiment.

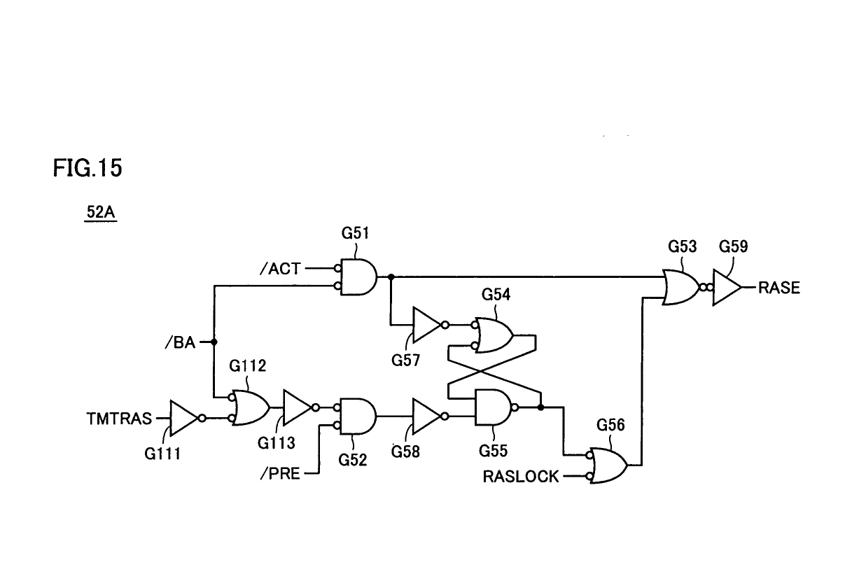

FIG. 15 is a circuit diagram showing a configuration of internal RAS generating circuit 52A shown in FIG. 13.

Referring to FIG. 15, internal RAS generating circuit 52A further includes inverters G111, G113, and an NAND gate G112 in the configuration of internal RAS generating circuit 52 in the first embodiment. Inverter G111 outputs an inverted signal of test mode signal TMTRAS. NAND gate G112 performs AND operation of internal bank address signal /BA and an output signal from inverter G111, and outputs a signal obtained by inverting the operation result. Inverter G113 outputs a signal obtained by inverting an output signal from NAND gate G112 to one input terminal of NAND gate G52.

In internal RAS generating circuit 52A, when test mode signal TMTRAS is at H level, an output of inverter G113 attains L level regardless of internal bank address signal /BA. Therefore, even when internal bank address signal /BA is not asserted (L level), precharge signal /PRE attaining L level at the timing of rise of row address strobe signal ext./RAS can be used to set internal signal RASE to L level.

On the other hand, when test mode signal TMTRAS is at L level, the logic level of internal bank address signal /BA appears at an output of inverter G113. Therefore, in the normal operation mode, internal RAS generating circuit 52A serves as a circuit equivalent to internal RAS generating circuit 52 in the first embodiment, and operates in a manner similar to the same.

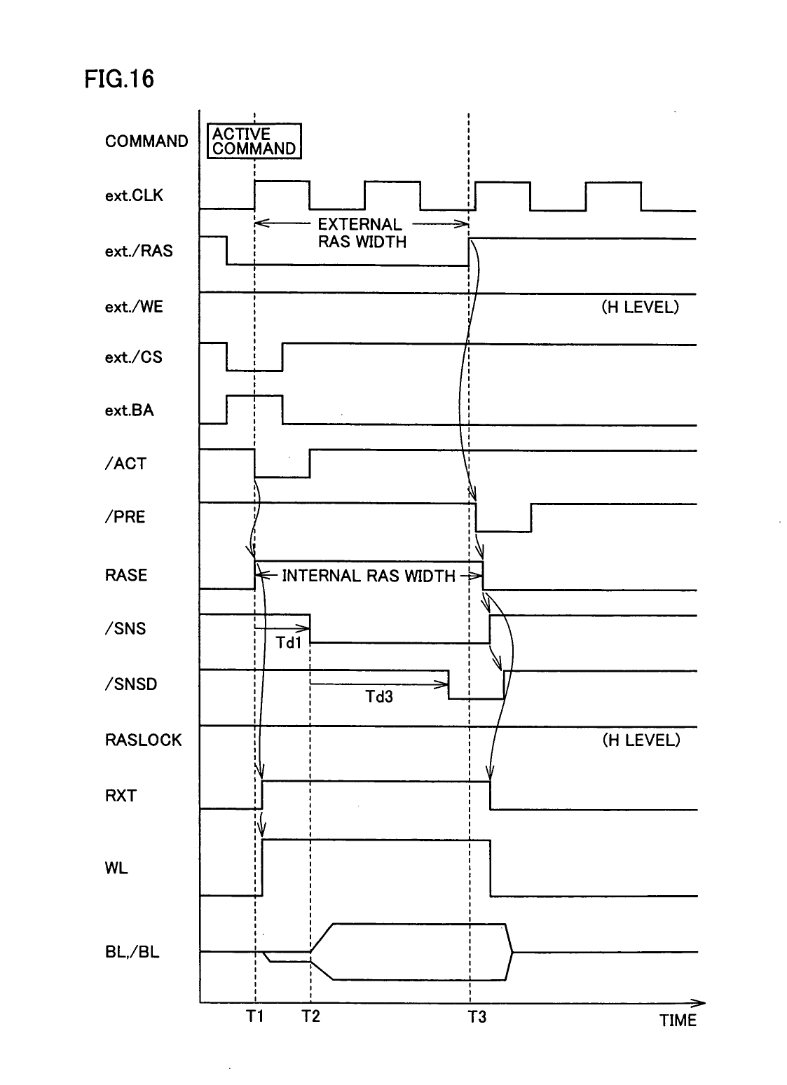

FIG. 16 is an operational waveform diagram of primary signals in the test mode in semiconductor memory device 10A in the second embodiment. As described above, in the normal operation mode, command decoder 26A and internal RAS generating circuit 52A operate in a manner similar to command decoder 26 and internal RAS generating circuit 52 in semiconductor memory device 10 respectively. Accordingly, the operational waveform of semiconductor memory device 10A in the normal operation mode is the same as that of semiconductor memory device 10 in the first embodiment.

Referring to FIG. 16, though not shown, test mode signal TMTRAS is always at H level, and the test mode is designated. The operations at time T1, T2 in response to fall of active signal /ACT are the same as those in semiconductor memory device 10 in the first embodiment.

When row address strobe signal ext./RAS rises at time T3 asynchronously to external clock ext.CLK, command decoder 26A sets precharge signal /PRE to L level. Then, internal RAS generating circuit 52A sets internal signal RASE to L level, and in response to this, word line activation signal generating circuit 54 sets word line activation signal RXT to L level. Word line activation circuit 36 inactivates the word line that has been activated.

As described above, according to semiconductor memory device 10A in the second embodiment, in the test mode, precharge signal /PRE is asserted (L level) at the timing of rise of row address strobe signal ext./RAS, and the internal RAS width is controlled by the falling width of row address strobe signal ext./RAS.

Thus, the RAS width can be made smaller asynchronously to external clock ext.CLK without being affected by the operation frequency of the measuring equipment. Therefore, the operation margin test eliminating a memory cell with insufficient current drivability can be conducted.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device continuing an access operation to a memory cell storing data at least until a prescribed period elapses, upon receiving a first control command to start access to said memory cell in a normal operation mode, comprising:
a word line and a bit line pair connected to said memory cell; and
a control circuit controlling said access operation based on a control command received from outside; wherein
said prescribed period is a period in which restoration of said data to said memory cell is completed,
said control circuit terminates control of said access operation in response to a second control command received from the outside regardless of elapse of said prescribed period, upon receiving said first control command in a test mode.

2. The semiconductor memory device according to claim 1, wherein
said second control command is a precharge command instructing precharge of said bit line pair.

3. The semiconductor memory device according to claim 1, further comprising a command decoder determining a type of said control command based on a control signal received from the outside, wherein
said command decoder determines that said second control command is received from the outside, when a prescribed control signal asynchronous to an external clock received by the semiconductor memory device is inactivated.

4. The semiconductor memory device according to claim 3, wherein
said prescribed control signal is a row address strobe signal activated corresponding to said first control command.

5. The semiconductor memory device according to claim 1, further comprising a word line activation circuit activating said word line based on an operation instruction received from said control circuit, wherein
said control circuit includes
a guarantee signal generating circuit generating a guarantee signal for guaranteeing an active period of said word line, and
an internal signal generating circuit generating an internal signal instructing activation of said word line based on said first and second control commands and said guarantee signal received from said guarantee signal generating circuit, and outputting said generated internal signal to said word line activation circuit, at least when said guarantee signal is activated, and
said guarantee signal generating circuit activates said guarantee signal until said prescribed period elapses in said normal operation mode, and inactivates said guarantee signal in said test mode.

6. The semiconductor memory device according to claim 5, wherein
said guarantee signal generating circuit includes
a delay circuit generating a signal delayed by said prescribed period from said internal signal generated by said internal signal generating circuit, and
an output circuit generating said guarantee signal based on an output signal from said delay circuit and a test mode signal activated in said test mode, and outputting said generated guarantee signal to said internal signal generating circuit.
